(19) United States
(12) Patent Application Publication
(10) Pub. No.: US 2026/0107387 A1
(43) Pub. Date: Apr. 16, 2026

(54) ASSEMBLIES INCLUDING ELECTRONIC COMPONENTS BONDED TO SUBSTRATES

(71) Applicant: Honeywell International Inc., Charlotte, NC (US)

(72) Inventors: Vitan Georgievski, Tampa, FL (US); John Fredy Arroyave, Tampa, FL (US)

(21) Appl. No.: 18/917,562

(22) Filed: Oct. 16, 2024

(51) Int. Cl. H05K 1/181

(52) U.S. Cl. CPC H05K 1/181; H05K 2201/10242; H05K 2201/10325

(57) ABSTRACT

An assembly may include an electronic substrate, an electronic component extending from the electronic substrate, and a bonding well surrounding at least a portion of the electronic component. The bonding well may define at least one opening configured to introduce a bonding composition within the bonding well.

### STATEMENT REGARDING FEDERALLY SPONSORED RESEARCH OR DEVELOPMENT

This invention was made with Government support under FA9453-22-C-0020 awarded by Air Force Research Laboratory. The Government has certain rights in the invention.

### TECHNICAL FIELD

The present disclosure relates to electronic components, for example, connectors and integrated circuits, and assemblies including electronic components bonded to substrates.

### BACKGROUND

Electronic components are utilized universally on many different circuit card assemblies to perform various electronic functions. Connectors may be used to mechanically and electrically couple electronic components. For example, a first electronic component on a first circuit board may be coupled by a connector to a second electronic component on a second circuit board.

### SUMMARY

In general, the present disclosure describes assemblies including electronic components and techniques for assembling electronic components. Electronic components, for example, circuit boards, may be electrically and/or mechanically coupled to each other using electronic connectors. An electrical connector may be secured to an electronic substrate (e.g., a circuit board) by a bonding composition (e.g., an epoxy composition). However, applying a consistent volume of bonding composition, and applying bonding composition in contact with a predetermined region or portion of the electrical connector repeatedly to a large number of units in manufacturing may present difficulties. For example, a production line may need to be slowed down to apply a predetermined volume of a bonding composition to predetermined portions of electrical connectors and/or verify proper application.

In some examples, assemblies according to the present disclosure include bonding wells configured to facilitate applying a predetermined volume of a bonding composition to a predetermined region of an electronic component. For example, a bonding well may be secured about a predetermined region of the electronic component, and the bonding well may define an interior volume configured to receive and hold a predetermined volume of the bonding composition. The bonding well may define at least one opening for introducing the bonding composition within the bonding well. For example, the bonding well may initially be secured about the electronic component, followed by introduction of the bonding composition into the bonding well, into contact with a predetermine region of the electronic component adjacent the bonding well. Promoting consistency and repeatability of bonding processes for these components may in turn improve the long-term durability and reliability of circuitry, for example, circuit card assemblies.

In some examples, the present disclosure describes an example assembly including an electronic substrate, an electronic component extending from the electronic substrate, and a bonding well surrounding at least a portion of the electronic component. The bonding well may define at least one opening configured to introduce a bonding composition within the bonding well.

In some examples, the present disclosure describes an example method including aligning a first electronic component extending away from a first electronic substrate through a first apex window of a first bonding well with a second electronic component by moving the first electronic component through a second apex window of a second bonding well. The method may further include reducing a spacing between the first electronic component and the second electronic component. The second electronic component may extend from a second electronic substrate opposing the first electronic substrate. The first bonding well may surround at least a portion of the first electronic component and define a first opening configured to introduce a bonding composition within the first bonding well. The second bonding well may surround at least a portion of the second electronic component and define a second opening configured to introduce the bonding composition within the second bonding well.

The details of one or more examples are set forth in the accompanying drawings and the description below. Other features, objects, and advantages will be apparent from the description and drawings, and from the claims.

### BRIEF DESCRIPTION OF THE FIGURES

The details of one or more examples are set forth in the accompanying drawings and the description below. Other features, objects, and advantages will be apparent from the description and drawings, and from the claims.

FIG. 1A is a diagram showing a front view of an example assembly including an electronic substrate, an electronic component, and a bonding well.

FIG. 1B is a diagram showing a top view of the assembly of FIG. 1A.

FIG. 1C is a diagram showing a partial front view of the assembly of FIG. 1A with the electronic component ready to receive the bonding well about the electronic component.

FIG. 2A is a partial perspective view of an example assembly including pairs of electronic substrates, electronic components, and bonding wells.

FIG. 2B is a partial side view of the assembly of FIG. 2A.

FIG. 2C is a perspective view of a first bonding well of the assembly of FIG. 2A.

FIG. 2D is a perspective view of a second bonding well of the assembly of FIG. 2A.

FIG. 3A is a diagram showing a front view of an example assembly including an electronic substrate, an electronic component, and a bonding well configured to bond a face of the electronic component.

FIG. 3B is a diagram showing a perspective view of the bonding well of FIG. 3A.

FIG. 4A is a diagram showing a top view of an example assembly including an electronic substrate, an electronic component, and a bonding well configured to bond a corner of the electronic component.

FIG. 4B is a diagram showing a perspective view of the bonding well of FIG. 4A.

FIG. 5 is a flowchart representing a method for engaging the first electronic component with the second electronic component.

### DETAILED DESCRIPTION

In general, the disclosure describes assemblies including electronic components and techniques for assembling electronic components.

Electronic components, for example, connectors used in electronic packaging, may benefit from structural reinforcement. For example, connectors or other electronic components may be secured to substrates such as circuit boards. Pins and/or bonding compositions may be used to promote securement of connectors to substrates. However, in certain situations, achieving a consistent or repeatable volume of a bonding composition (e.g., epoxy) applied to a connector may be difficult while maintaining a relatively fast production speed. For example, the bonding composition may be applied beyond a predetermined region or portion of the connector, leading to wastage of the composition, or may be absent from the predetermined region or portion, which may form gaps or pockets.

Bonding wells according to the present disclosure may be used to facilitate applying predetermined volumes of bonding compositions to predetermined regions or portions of electronic components, with relative rapidity and accuracy. Thus, the bonding wells may promote securing electronic components to substrates. For example, the bonding wells may promote durability and long-term life expectancy of electronic components (e.g., connectors). In some examples, the bonding wells may be used for connectors of aerospace components. However, assemblies, structures, and techniques according to the present disclosure may be used in any suitable components, for example, for commercial, industrial, residential, electronic, consumer product, or transport applications.

In some examples, the present disclosure describes an example assembly including an electronic substrate, an electronic component extending from the electronic substrate, and a bonding well surrounding at least a portion of the electronic component. The bonding well may define at least one opening configured to introduce a bonding composition within the bonding well. The bonding well may facilitate relative rapid introduction and retention of a predetermined volume of the bonding composition in secure contact with the portion of the electronic component. The at least one opening may facilitate introduction of the bonding composition into an interior of the bonding well, for example, from a tube, pipe, syringe, or other conveyance.

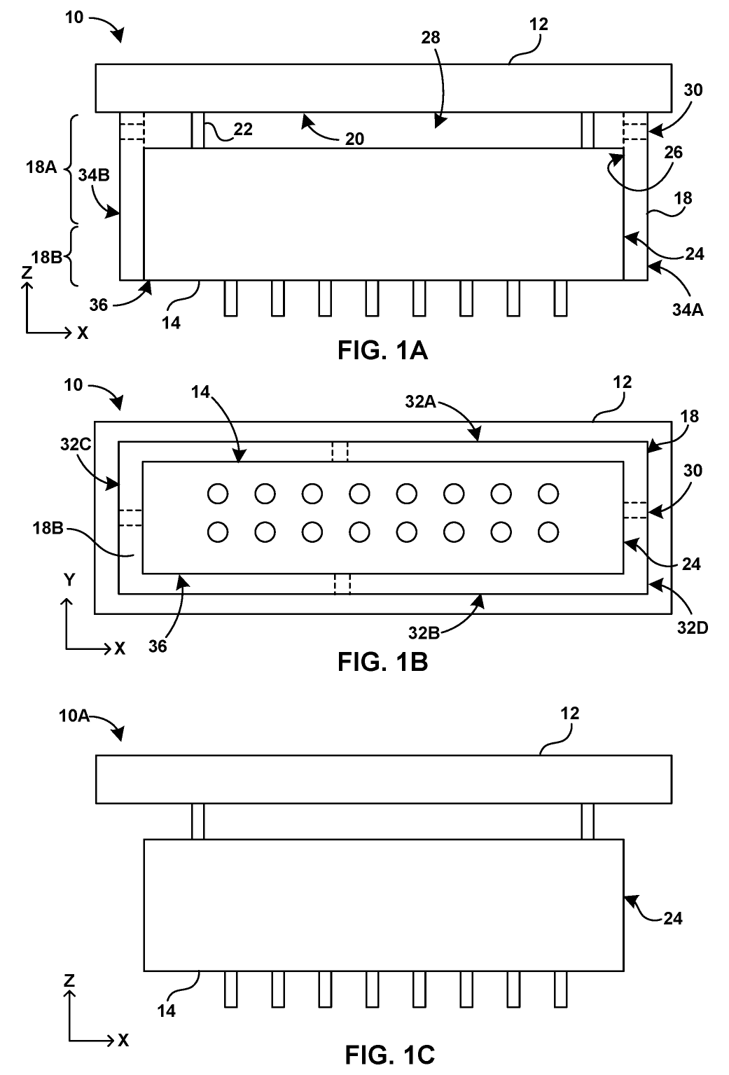

FIG. 1A is a diagram showing a front view of an example assembly 10 including an electronic substrate 12, an electronic component 14, and a bonding well 18. FIG. 1B is a diagram showing a top view of assembly 10 of FIG. 1A. Electronic substrate 12 may include any suitable substrate on which one or more electronic components may be secured, for example, a circuit board or a housing. Electronic substrate 12 may include one or more electronic components, traces, conductive paths, or any suitable circuitry. In some examples, at least one other electronic component is electrically connected to electronic component 14. In some examples, electronic component 14 includes a connector. In some examples, electronic substrate 12 defines a major surface 20 facing electronic component 14.

Electronic component 14 may be configured to be mechanically and/or electronically connectable to another electronic component (e.g., of another assembly). For example, a first component of assembly 10 of electronic substrate 12 may be coupled to a second component via an electrical connection through another component of another assembly. Electronic component 14 extends from electronic substrate 12. For example, electronic component 14 may extend from major surface 20 of electronic substrate in a direction substantially normal to major surface 20.

In some examples, electronic component 14 includes at least one mounting pin 22 configured to engage with or be received by a portion of electronic substrate 12. For example, mounting pin 22 may be receivable within a substrate connector, a slot, or a bore defined by electronic substrate 12. Thus, electronic component 14 may be at least partially secured to electronic substrate 12 by mounting pin 22. In some examples, assembly 10 includes two or more mounting pins 22. In some examples, mounting pin 22 (or another structure) may be further configured to electrically couple electronic component 14 to at least one component of assembly 10. For example, the at least one component may be electrically coupled (e.g., by a trace or any suitable conductive path) to the substrate connector, and electrical contact between mounting pin 22 and the substrate connector may ultimately connect electronic component 14 to the at least one component electrically.

In some examples, bonding well 18 is configured to shield electronic component 14 from one or both of electrostatic discharge or foreign object debris. Bonding well 18 may surround at least a portion of electronic component 14. For example, electronic component 14 may define at least one component face 24, and bonding well 18 may face or contact at least one component face 24. At least a portion of bonding well 18 may be in contact with a portion of at least one component face 24, or in contact with an entirety of component face 24, or spaced from the portion of at least one component face 24. For example, bonding well 18 may define at least one interior well face 26 facing at least one component face 24, and at least a portion of or an entirety of at least one interior well face 26 may contact or be spaced from at least a portion of or an entirety of at least one component face 24.

One or both of at least one component face 24 or at least one interior well face 26 may be planar or curved, and have any suitable shape or contour. In some examples, electronic component 14 and/or bonding well 18 may define a polygonal (e.g., rectangular or square) cross-section across a plane (e.g., along an XY plane). In some examples, electronic component 14 and/or bonding well 18 define a polygonal cross-section with rounded vertices (e.g., a rounded rectangle or rounded square). In some examples, the cross-section of electronic component 14 and/or bonding well 18 is constant along a respective height (e.g., along a Z direction). In other examples, the cross-section of electronic component 14 and/or bonding well 18 varies along the height, for example, increasing or decreasing along at least a portion of a height. In some examples, the cross-section of electronic component 14 and/or bonding well 18 is constant along a first portion of a height, and varies along a second portion of the height. In some examples, electronic component 14 defines a constant cross-section along an entire height of electronic component 14, while bonding well 18 exhibits a varying cross-section at least along a portion of a height of bonding well 18. Such a configuration may define one or more pockets between electronic component 14 and bonding well 18 within which the bonding composition may be received and retained.

Bonding well 18 defines a well chamber 28 (for example, defined by at least one interior well face 26). Well chamber 28 is configured to receive a bonding composition. The bonding composition may be configured to bond electronic component 14 to electronic substrate 12, and may include any suitable bonding agent. In some examples, the bonding composition includes an epoxy composition, a cyanoacrylate composition, a silicone composition, a polyurethane composition, or any other adhesive composition. The bonding composition may be self-curing (e.g., without requiring the application of a curing agent or curing energy) or externally curable (e.g., cured upon exposure to a curing agent or curing energy). In some examples, the bonding composition is thermally-curable, light-curable (e.g., UV curable), or chemically curable (e.g., upon exposure to a curing agent). The bonding composition may be a liquid (e.g., a runny or a viscous liquid), a gel, a paste, a putty, or in any other form. The bonding composition may be transparent, translucent, or opaque.

Bonding well 18 may be formed of any suitable material, for example, one or more of a metal, an alloy, a glass, a ceramic, or a polymer. In some examples, bonding well 18 includes, consists of, or consists essentially of, a polymeric composition. The polymeric composition may include one or more polymers. In some examples, bonding well 18 includes one or more of a polycarbonate, an acrylonitrile butadiene styrene, a polyamide, a polybutylene terephthalate, polypropylene, polyethylene, a silicone, a polyvinyl carbonate, a polymethylmethacrylate, a nylon, an acrylate, or a fluoropolymer. In some examples, at least a portion of bonding well 18 is transparent, translucent, or opaque. In some examples, an entirety of bonding well 18 is transparent or translucent. For example, a transparent or translucent bonding well 18 may facilitate inspection of an interior of bonding well 18, of a configuration of bonding composition within well chamber 28, of a portion of electronic component 14 within well chamber 28, or curing of bonding composition within well chamber 28 (e.g., by photocuring by passing light of a predetermined frequency or frequency band through bonding well 18).

Well chamber 28 may be dimensioned to receive and retain the bonding composition in contact with a predetermined portion or region of electronic component 14. In some examples, well chamber 28 is configured to contact a surface of electronic component 14 facing major surface 20 of electronic substrate, or another surface of electronic component 14, or an interface between electronic component 14 and bonding well 18 with the bonding composition. Thus, bonding well 18 may include the bonding composition retained within bonding well 18 (e.g., in well chamber 28) and in contact with at least a portion of electronic component 14.

Bonding well 18 may define at least one opening 30 configured to introduce the bonding composition within bonding well 18 (e.g., within well chamber 28). In some examples, at least one opening 30 includes at least one port defined by a wall of bonding well 18 (e.g., extending through a thickness of the wall of bonding well 18). In some examples, at least one opening 30 is at least partially defined by one or more edges or peripheral portions of bonding well 18. At least one opening 30 may have any suitable cross-section, for example, circular, elliptical, polygonal, or any suitable shape or configuration. At least one opening 30 may extend along a straight line, an inclined path (e.g., inclined along one or more of X, Y, or Z directions) or along a curved or zigzag path. In some examples, at least one opening 30 narrows in a direction from an exterior of bonding well 18 toward well chamber 28. For example, such narrowing may facilitate introduction of bonding composition through at least one opening 30 within well chamber 28, while resisting departure of the bonding composition from at least one opening 30 to an exterior of bonding well 18. At least one opening 30 may extend across a wall of bonding well 18, for example, a wall defining at least one interior well surface 26. Bonding well 18 may define one, two, three, four, or more openings 30. In some examples, bonding well 18 defines a plurality of walls, and one or more wall of bonding well 18 may define at least one opening 30.

In some examples, bonding well 18 consists of a unitary well body. For example, bonding 18 may be additively manufactured, molded, stamped, or otherwise formed. In some examples, the unitary well body defines at least one opening 30. Bonding well 18 may define a uniform well thickness along a portion of or an entirety of bonding well 18. In some examples, each wall of bonding well has a same thickness.

In some examples, bonding well 18 defines a first pair of opposing walls 32A and 32B extending between a first end 34A and a second end 34B of bonding well 18. In some examples, bonding well 18 defines a second pair of opposing walls 32C and 32D extending between first pair of walls 32A and 32B. For example, first pair of walls 32A and 32B may be longer than second pair of walls 32C and 32D. In some examples, at least one opening 30 is defined by at least one wall of first pair of opposing walls 32A or 32B or second pair of opposing walls 32C or 32D. At least one opening 30 may include a first opening defined by one wall of first pair of opposing walls 32A or 32B and a second opening defined by one wall of second pair of opposing walls 32C or 32D (or by the other wall of first pair of opposing walls 32A or 32B). In some examples, bonding well 18 defines a single opening 30 (such that no more than one opening is present).

In some examples, bonding well 18 includes a base well portion 18A facing electronic substrate 12 and an apex well portion 18B away from electronic substrate 12. In some examples, at least one opening 30 is defined by base well portion 18A of bonding well 18. In some examples, the base well portion 18A includes at least one inclined wall, where the inclined wall is inclined relative to apex well portion 18B. In some examples, base well portion 18A has a maximum width (e.g., in a X or Y direction) that is greater than a maximum width of apex well portion 18A.

Apex well portion 18B may define an apex window 36 opposing electronic substrate 12. In some examples, electronic component 14 extends in a direction away from electronic substrate 12 toward apex window 36 (for example, along a Z direction). A portion of electronic component 14 may extend from well chamber 28 to an exterior of bonding well 18 through apex window 36 (e.g., along the Z direction).

FIG. 1C is a diagram showing a partial front view of assembly 10 of FIG. 1A in a configuration 10A with electronic component 14 ready to receive bonding well 18 about electronic component 14. In configuration 10A, the bonding composition may be absent, and may be introduced only after bonding well 18 is disposed about electronic component 14. In other examples, at least a partial volume of the bonding composition may be applied to at least a portion or a region of electronic component 14 before bonding well 18 is positioned (e.g., between electronic component 14 and major surface 20 of electronic substrate 12), and at least a partial volume of the bonding composition may be introduced after bonding well 18 is positioned. Thus, assembly 10 shown in FIGS. 1A and 1B may be achieved after bonding well 18 is positioned about electronic component 14 in configuration 10A.

Thus, bonding well 18 may be used to promote introduction and retention of a bonding composition to facilitate securing electronic component 14 to electronic substrate 12. For example, electronic component 14 may be repeatedly coupled to and uncoupled from another electronic component (e.g., a connector) of another assembly while remaining secured to electronic substrate 12.

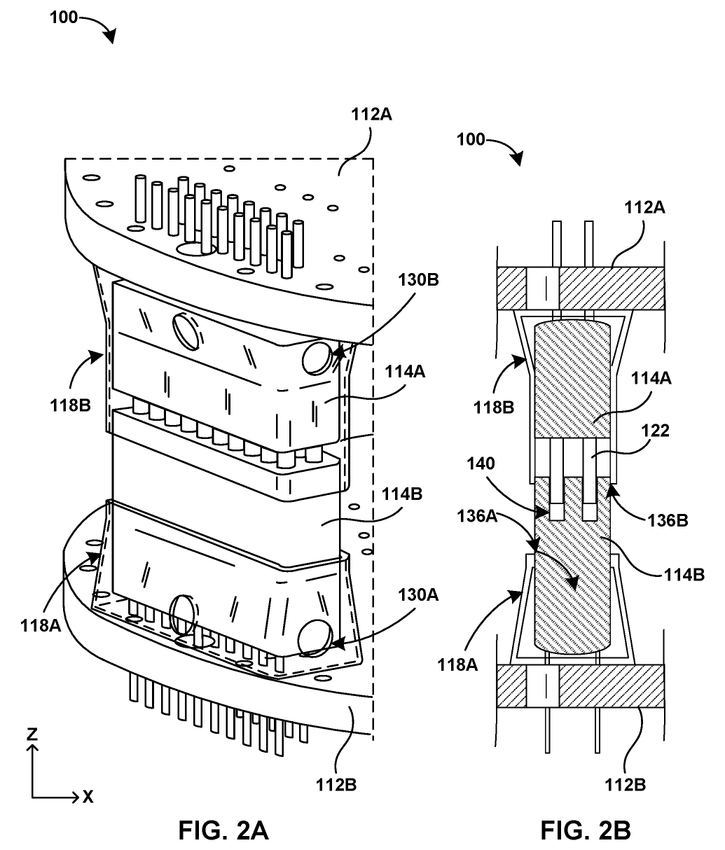

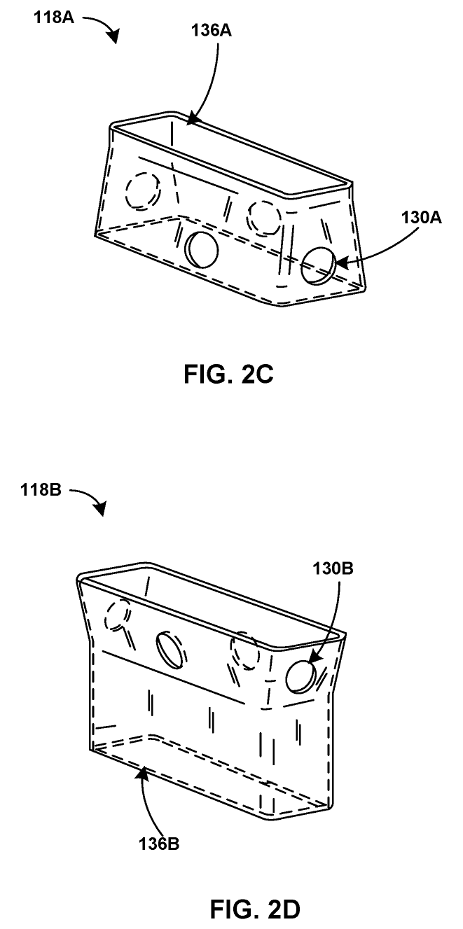

FIG. 2A is a partial perspective view of an example assembly 100 including pairs of electronic substrates 112A and 112B, electronic components 114A and 114B, and bonding wells 118A and 118B. FIG. 2B is a partial side view of assembly 100 of FIG. 2A. FIG. 2C is a perspective view of first bonding well 118A of assembly 100 of FIG. 2A. FIG. 2D is a perspective view of second bonding well 118B of assembly 100 of FIG. 2A.

Like components are numbered alike in assembly 10 of FIGS. 1A and 1B and assembly 100 of FIG. 2A. For example, electronic substrates 112A and 112B may be similar to or the same as electronic substrate 12, electronic components 114A and 114B may be similar to or the same as electronic component 14, and bonding wells 118A and 118B may be similar to or the same as bonding well 18, described with reference to FIGS. 1A and 1B. In some examples, one or both of electronic component 114A and electronic component 114B includes or is a connector. For example, first electronic component 114A may include a first connector, and second electronic component 114B may include a second connector.

For example, assembly 100 may include a first electronic substrate 112A, a first electronic component 114A, and a first bonding well 118A. First bonding well 118A may define at least one opening 130A, similar to or the same as opening 30 described with reference to FIGS. 1A and 1B. Assembly 100 may further include a second electronic substrate 112B opposing first electronic substrate 112A, a second electronic component 114B extending from second electronic substrate 112B and configured to couple with first electronic component 114A, and a second bonding well 118B surrounding at least a portion of second electronic component 114B and defining at least one opening 130B configured to introduce a bonding composition within second bonding well 118B.

In some examples, first bonding well 118A has a first height in a direction normal to first electronic substrate 112A, and second bonding well 118B has second height in a direction normal to second electronic substrate 112B. In some examples, the second height is greater than the first height. For example, one or both of an apex well portion or a base well portion of second bonding well 118B may be taller than a respective apex well portion or a base well portion of first bonding well 118A. In some examples, first bonding well 118A has a relatively short apex well portion, while second bonding well 118B has an elongated apex well portion.

In some examples, first bonding well 118A defines a first apex window 136A, second bonding well 118B defines a second apex window 136B, and first electronic component 114A extends from first bonding well 118A through first apex window 136A and second apex window 136B into engagement with second electronic component 114B within second bonding well 118B.

First electronic component 114A may define a plurality of slots 140, and the second electronic component includes a plurality of pins 122. In some examples, first bonding well 118A and second bonding well 118B align plurality of pins 122 with plurality of slots 140 when first electronic component 114A extends through first apex window 136A and second apex window 136B.

Bonding composition is present within respective well chambers of first bonding well 118A and second bonding well 118B (not shown in the figures). Thus, first bonding well 118A and second bonding well 118B may respectively secure first electronic component 114A and second electronic component 114B to first electronic substrate 112A and second electronic substrate 112B while first electronic component 114A and second electronic component 114B are coupled to each other.

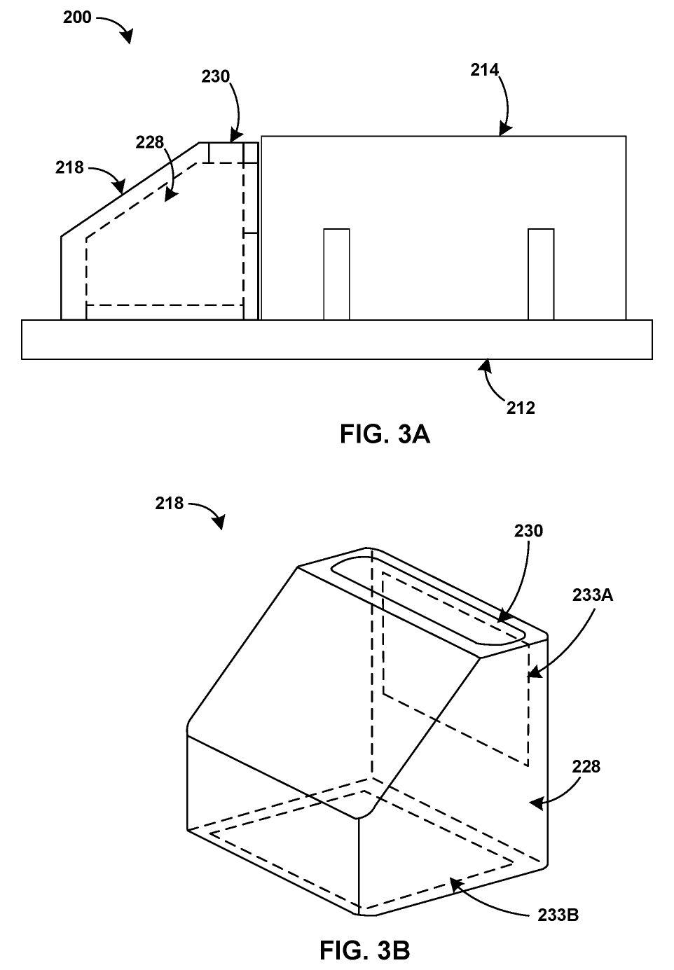

FIG. 3A is a diagram showing a front view of an example assembly 200 including an electronic substrate 212, an electronic component 214, and a bonding well 218 configured to bond a face of electronic component 214. FIG. 3B is a diagram showing a perspective view of bonding well 218.

Bonding well 218 may be similar in construction and composition to bonding well 18 described with reference to FIGS. 1A to 1C, but differ in the overall shape and configuration. Bonding well 218 is configured to contact, abut, or face at least a portion of electronic component 214. Bonding well 218 defines at least one opening 230 configured to introduce a bonding composition into a bonding chamber 228. Bonding well 218 may further define at least one window, for example, a first window 233A and a second window 233B. In some examples, first window 233A is configured to face electronic component 214, such that bonding composition from bonding chamber 228 may contact electronic component 214 through first window 233A. First window 233A may be spaced from at least one opening 230 (as shown in FIG. 3B), or may be contiguous with at least one opening 230. In some examples, second window 233B is configured to face electronic substrate 212, such that bonding composition from bonding chamber 228 may contact electronic substrate 212 through second window 233B.

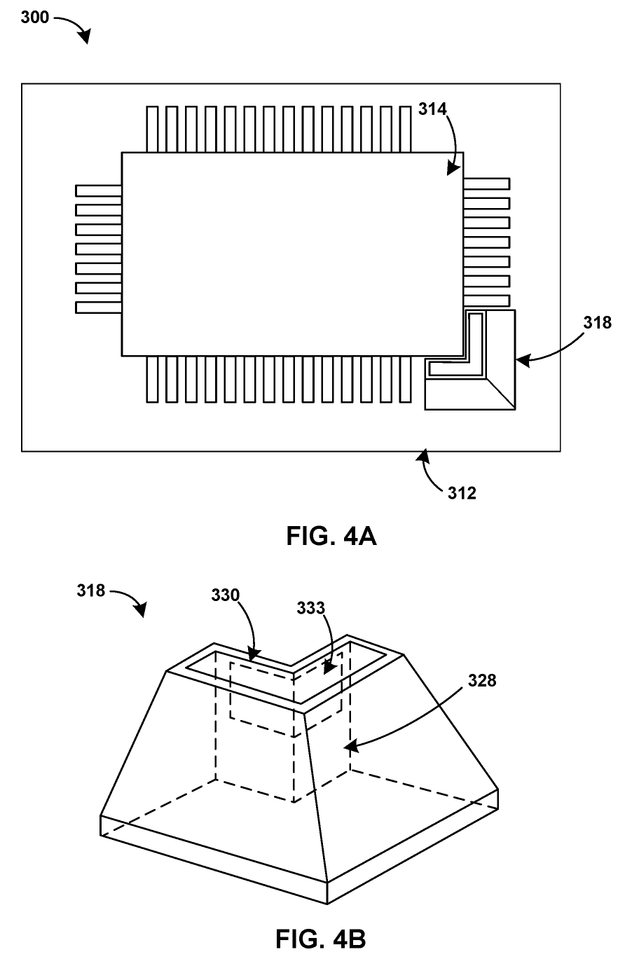

FIG. 4A is a diagram showing a top view of an example assembly 300 including an electronic substrate 312, an electronic component 314, and a bonding well 318 configured to bond a corner of electronic component 314. FIG. 4B is a diagram showing a perspective view of bonding well 318 of FIG. 4A.

Bonding well 318 may be similar in construction and composition to bonding well 18 described with reference to FIGS. 1A to 1C, but differ in the overall shape and configuration. Bonding well 318 is configured to contact, abut, or face at least a portion (e.g., a corner) of electronic component 314. Bonding well 318 defines at least one opening 330 configured to introduce a bonding composition into a bonding chamber 328. Bonding well 318 may further define at least one window, for example, a window 333. Window 333 may be spaced from at least one opening 330 (as shown in FIG. 4B), or may be contiguous with at least one opening 330. In some examples, window 333 is configured to face electronic component 314 (e.g., a corner of electronic component 314), such that bonding composition from bonding chamber 328 may contact electronic component 314 through window 333. In some examples, bonding well 318 may further define another window configured to face electronic substrate 312, such that bonding composition from bonding chamber 328 may contact electronic substrate 312 through second window 333.

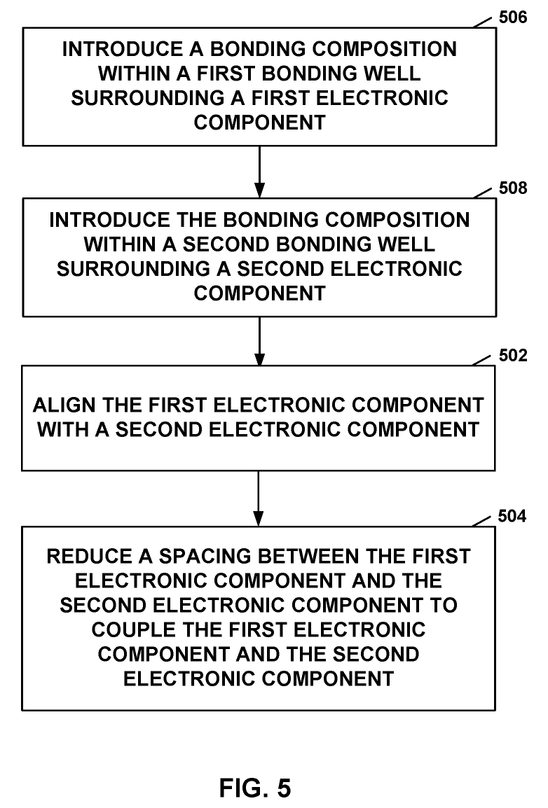

FIG. 5 is a flowchart representing a method for engaging first electronic component 114A with second electronic component 114B. While the method of FIG. 5 is described with reference to assembly 100 of FIGS. 2A and 2B as an example, the method of FIG. 5 may be performed using any suitable assembly according to the present disclosure, and the assembly of FIGS. 2A and 2B may be assembled using any suitable technique according to the present disclosure. The method may include aligning first electronic component 114A extending away from first electronic substrate 112A through first apex window 136A of first bonding well 118A with second electronic component 114B by moving first electronic component 114A through second apex window 136B of second bonding well 118B (502). The method may further include reducing a spacing between first electronic component 114A and second electronic component 114B (504). For example, the reducing the spacing (504) may cause first electronic component 114A to be coupled with second electronic component 114B, while second electronic component 114B extends from second electronic substrate 112B opposing first electronic substrate 112A. First bonding well 118A may surround at least a portion of first electronic component 114A and define first opening 130A configured to introduce a bonding composition within first bonding well 118A. Second bonding 118B well may surround at least a portion of second electronic component 114B and define second opening 130B configured to introduce the bonding composition within second bonding well 118B.

The method may further include, before aligning first electronic component 114A with second electronic component 114B (502), sliding first bonding well 118A over first electronic component 114A toward first electronic substrate 112A to cause first bonding well 118A to surround at least a portion of first electronic component 114A. The method may further include, before aligning first electronic component 114A with second electronic component 114B (502), sliding second bonding well 118A over second electronic component 114B toward second electronic substrate 112B to cause second bonding well 118B to surround at least a portion of second electronic component 114B.

The method may further include, before the aligning (502), introducing the bonding composition within first bonding well 118A through first opening 130A defined by first bonding well 130A (506). The method may further include, before the aligning (502), introducing the bonding composition within second bonding well 118B through second opening 130B defined by second bonding well 118B (508). The bonding composition may be cured within first bonding well 118A and/or second bonding well 118B to respectively secure first electronic component 114A and second electronic component 114B to first electronic substrate 112A and second electronic substrate 112B. Any suitable curing technique may be used based on the nature of the bonding composition, for example, dehydration, drying, chemical curing, thermal curing, light curing, or combinations thereof.

In some examples, introducing the bonding composition may be at least performed after the aligning (502) and/or the reducing the spacing (504) in addition to, or instead of, at least partially introducing the bonding composition in first bonding well 118A (506) or in second bonding well 118B (508). For example, introducing the bonding composition within first bonding well 118A may be performed before or after aligning first electronic component 114A with second electronic component 114B (502), and introducing the bonding composition second first bonding well 118B may be performed before or after aligning first electronic component 114A with second electronic component 114B.

The following enumerated clauses describe examples according to the present disclosure.

Clause 1: An assembly including: an electronic substrate; an electronic component extending from the electronic substrate; and a bonding well surrounding at least a portion of the electronic component and defining at least one opening configured to introduce a bonding composition within the bonding well.

Clause 2: The assembly of clause 1, where the at least one opening includes at least one port defined by a wall of the bonding well.

Clause 3: The assembly of clauses 1 or 2, where the bonding well defines a first pair of opposing walls extending between a first end and a second end of the bonding well.

Clause 4: The assembly of clause 3, where the bonding well defines a second pair of opposing walls extending between the first pair of walls.

Clause 5: The assembly of clause 4, where the first pair of walls is longer than the second pair of opposing walls.

Clause 6: The assembly of clauses 3 or 4, where the at least one opening is defined by at least one wall of the first pair of opposing walls or the second pair of opposing walls.

Clause 7: The assembly of any of clauses 3 to 6, where the at least one opening includes a first opening defined by one wall of the first pair of opposing walls and a second opening defined by one wall of the second pair of opposing walls.

Clause 8: The assembly of clauses 1 to 7, where the bonding well includes a base well portion facing the electronic substrate and an apex well portion away from the electronic substrate, and where the at least one opening is defined by the base well portion of the bonding well.

Clause 9: The assembly of clause 7, where the base well portion includes at least one inclined wall, where the inclined wall is inclined relative to the apex well portion.

Clause 10: The assembly of clauses 8 or 9, where the base well portion has a maximum width that is greater than a maximum width of the apex well portion.

Clause 11: The assembly of any of clauses 8 to 10, where the apex well portion defines an apex window opposing the electronic substrate.

Clause 12: The assembly of clause 11, where the electronic component extends in a direction away from the electronic substrate toward the apex window.

Clause 13: The assembly of clauses 11 or 12, where the bonding well defines a well chamber, and where a portion of the electronic component extends from the well chamber to an exterior of the bonding well through the apex window.

Clause 14: The assembly of any of clauses 1 to 13, where at least a portion of the bonding well is transparent or translucent.

Clause 15: The assembly of any of clauses 1 to 14, where an entirety of the bonding well is transparent.

Clause 16: The assembly of any of clauses 1 to 15, where the bonding well consists of a unitary well body, and where the unitary well body defines the at least one opening.

Clause 17: The assembly of any of clauses 1 to 16, where the bonding well is additively manufactured.

Clause 18: The assembly of any of clauses 1 to 17, where the bonding well is configured to shield the electronic component from one or both of electrostatic discharge or foreign object debris.

Clause 19: The assembly of any of clauses 1 to 18, where the bonding well defines a uniform well thickness along an entirety of the bonding well.

Clause 20: The assembly of any of clauses 1 to 19, where the bonding well includes the bonding composition retained within the bonding well and in contact with at least a portion of the electronic component.

Clause 21: The assembly of any of clauses 1 to 20, where the electronic substrate is a first electronic substrate, where the electronic component is a first electronic component, and where the bonding well is a first bonding well, the assembly further including: a second electronic substrate opposing the first electronic substrate; a second electronic component extending from the second electronic substrate; and a second bonding well surrounding at least a portion of the second electronic component and defining at least one opening configured to introduce the bonding composition within the second bonding well.

Clause 22: The assembly of clause 21, where the first bonding well has a first height in a direction normal to the first electronic substrate, where the second bonding well has second height in a direction normal to the second electronic substrate, and where the second height is greater than the first height.

Clause 23: The assembly of clauses 21 or 22, where the first bonding well defines a first apex window, where the second bonding well defines a second apex window, and where the first electronic component extends from the first bonding well through the first apex window and the second apex window into engagement with the second electronic component within the second bonding well.

Clause 24: The assembly of clause 23, where the first electronic component defines a plurality of slots, where the second electronic component includes a plurality of pins, and where the first bonding well and the second bonding well align the plurality of pins with the plurality of slots when the first electronic component extends through the first apex window and the second apex window.

Clause 25: The assembly of any of clauses 1 to 24, where the electronic component includes a connector.

Clause 26: A method including: aligning the first electronic component of any of clauses 21 to 24 with the second electronic component of any of clauses 21 to 24 by moving the first electronic component through the second apex window of the second bonding well; and reducing a spacing between the first electronic component and the second electronic component.

Clause 27: The method of clause 26, further including, before aligning the first electronic component with the second electronic component: sliding the first bonding well over the first electronic component toward the first electronic substrate to cause the first bonding well to surround at least a portion of the first electronic component; and sliding the second bonding well over the second electronic component toward the second electronic substrate to cause the second bonding well to surround at least a portion of the second electronic component.

Clause 28: The method of clauses 26 or 27, further including: introducing the bonding composition within the first bonding well through the first opening defined by the first bonding well; and introducing the bonding composition within the second bonding well through the second opening defined by the second bonding well.

Clause 29: The method of clause 28, wherein introducing the bonding composition within the first bonding well is performed before the aligning the first electronic component with the second electronic component, and wherein introducing the bonding composition within second first bonding well is performed before the aligning the first electronic component with the second electronic component.

Clause 30: The method of any of clauses 26 to 29, wherein the first electronic component includes a first connector, and wherein the second electronic component includes a second connector.

Various examples have been described. These and other examples are within the scope of the following claims.

What is claimed is:

1. An assembly comprising:
an electronic substrate;
an electronic component extending from the electronic substrate; and
a bonding well surrounding at least a portion of the electronic component and defining at least one opening configured to introduce a bonding composition within the bonding well.

2. The assembly of claim 1, wherein the at least one opening comprises at least one port defined by a wall of the bonding well.

3. The assembly of claim 1, wherein the bonding well defines a first pair of opposing walls extending between a first end and a second end of the bonding well.

4. The assembly of claim 3, wherein the bonding well defines a second pair of opposing walls extending between the first pair of walls.

5. The assembly of claim 4, wherein the first pair of walls is longer than the second pair of opposing walls.

6. The assembly of claim 3, wherein the at least one opening is defined by at least one wall of the first pair of opposing walls or the second pair of opposing walls.

7. The assembly of claim 3, wherein the at least one opening comprises a first opening defined by one wall of the first pair of opposing walls and a second opening defined by one wall of the second pair of opposing walls.

8. The assembly of claim 1, wherein the bonding well includes a base well portion facing the electronic substrate and an apex well portion away from the electronic substrate, and wherein the at least one opening is defined by the base well portion of the bonding well.

9. The assembly of claim 8, wherein the base well portion comprises at least one inclined wall, wherein the inclined wall is inclined relative to the apex well portion.

10. The assembly of claim 8, wherein the base well portion has a maximum width that is greater than a maximum width of the apex well portion.

11. The assembly of claim 8, wherein the apex well portion defines an apex window opposing the electronic substrate, and wherein the electronic component extends in a direction away from the electronic substrate toward the apex window.

12. The assembly of claim 11, wherein the bonding well defines a well chamber, and wherein a portion of the electronic component extends from the well chamber to an exterior of the bonding well through the apex window.

13. The assembly of claim 1, wherein at least a portion of the bonding well is transparent or translucent.

14. The assembly of claim 1, wherein the bonding well consists of a unitary well body, and wherein the unitary well body defines the at least one opening.

15. The assembly of claim 1, wherein the bonding well is configured to shield the electronic component from one or both of electrostatic discharge or foreign object debris.

16. The assembly of claim 1, wherein the bonding well comprises a bonding composition retained within the bonding well and in contact with at least a portion of the electronic component.

17. The assembly of claim 1, wherein the electronic substrate is a first electronic substrate, wherein the electronic component is a first electronic component, and wherein the bonding well is a first bonding well, the assembly further comprising:
a second electronic substrate opposing the first electronic substrate;
a second electronic component extending from the second electronic substrate; and
a second bonding well surrounding at least a portion of the second electronic component and defining at least one opening configured to introduce the bonding composition within the second bonding well.

18. The assembly of claim 17, wherein the first bonding well defines a first apex window, wherein the second bonding well defines a second apex window, wherein the first electronic component defines a plurality of slots, wherein the second electronic component comprises a plurality of pins, and wherein the first bonding well and the second bonding well align the plurality of pins with the plurality of slots when the first electronic component extends through the first apex window and the second apex window.

19. A method comprising:
aligning a first electronic component extending away from a first electronic substrate through a first apex window of a first bonding well with a second electronic component by moving the first electronic component through a second apex window of a second bonding well; and
reducing a spacing between the first electronic component and the second electronic component,
wherein the second electronic component extends from a second electronic substrate opposing the first electronic substrate,
wherein the first bonding well surrounds at least a portion of the first electronic component and defines a first opening configured to introduce a bonding composition within the first bonding well, and
wherein the second bonding well surrounds at least a portion of the second electronic component and defines a second opening configured to introduce the bonding composition within the second bonding well.

20. The method of claim 19, further comprising:
introducing the bonding composition within the first bonding well through the first opening defined by the first bonding well; and
introducing the bonding composition within the second bonding well through the second opening defined by the second bonding well.
